(19) United States
(12) Patent Application Publication
(10) Pub. No.: US 2003/0054645 A1
(43) Pub. Date: Mar. 20, 2003

(54) Method for fabricating a nozzle in silicon

(76) Inventor: Gary S. Sheldon, Aurora, NY (US)

Correspondence Address: Michael L. Goldman, NIXON PEABODY LLP, Clinton Square, P.O. Box 31051, Rochester, NY, 14603-1051, US

(21) Appl. No.: 10/246,132

(22) Filed: Sep. 17, 2002

Related U.S. Application Data
(60) Provisional application No. 60/323,034, filed on Sep. 17, 2001.

(51) Int. Cl. H01L 21/302; H01L 21/461

(52) U.S. Cl. 438/689

(57) ABSTRACT

A microchip-based electrospray device and method of fabrication thereof are disclosed. The electrospray device includes a substrate defining a channel between an entrance orifice on an injection surface and an exit orifice on an ejection surface, a nozzle defined by a portion recessed from the ejection surface surrounding the exit orifice, and an electric field generating source for application of an electric potential to the substrate to optimize and generate an electrospray. The method includes providing a nozzle and annulus pattern to the polished side of a wafer. The nozzle channel is etched and the back side of the wafer lapped or ground until the nozzle through channel is exposed. The annulus etch may be conducted prior to or following the backgrinding process.

This application claims the benefit of U.S. Provisional Patent Application Serial No. 60/323,034, filed Sep. 17, 2001, which is herein incorporated by reference in its entirety.

### FIELD OF THE INVENTION

The present invention relates generally to an integrated miniaturized fluidic system fabricated using Micro-ElectroMechanical System (MEMS) technology.

### BACKGROUND OF THE INVENTION

Electrospray ionization provides for the atmospheric pressure ionization of a liquid sample. The electrospray process creates highly-charged droplets that, under evaporation, create ions representative of the species contained in the solution. An ion-sampling orifice of a mass spectrometer may be used to sample these gas phase ions for mass analysis. When a positive voltage is applied to the tip of the capillary relative to an extracting electrode, such as one provided at the ion-sampling orifice of a mass spectrometer, the electric field causes positively-charged ions in the fluid to migrate to the surface of the fluid at the tip of the capillary. When a negative voltage is applied to the tip of the capillary relative to an extracting electrode, such as one provided at the ion-sampling orifice to the mass spectrometer, the electric field causes negatively-charged ions in the fluid to migrate to the surface of the fluid at the tip of the capillary.

When the repulsion force of the solvated ions exceeds the surface tension of the fluid being electrosprayed, a volume of the fluid is pulled into the shape of a cone, known as a Taylor cone, which extends from the tip of the capillary. A liquid jet extends from the tip of the Taylor cone and becomes unstable and generates charged-droplets. These small charged droplets are drawn toward the extracting electrode. The small droplets are highly-charged and solvent evaporation from the droplets results in the excess charge in the droplet residing on the analyte molecules in the electrosprayed fluid. The charged molecules or ions are drawn through the ion-sampling orifice of the mass spectrometer for mass analysis. This phenomenon has been described, for example, by Dole et al., Chem. Phys. 49:2240 (1968) and Yamashita et al., J. Phys. Chem. 88:4451 (1984). The potential voltage (“V”) required to initiate an electrospray is dependent on the surface tension of the solution as described by, for example, Smith, IEEE Trans. Ind. Appl. 1986, IA-22:527-35 (1986). Typically, the electric field is on the order of approximately 10⁶ V/m. The physical size of the capillary and the fluid surface tension determines the density of electric field lines necessary to initiate electrospray.

When the repulsion force of the solvated ions is not sufficient to overcome the surface tension of the fluid exiting the tip of the capillary, large poorly charged droplets are formed. Fluid droplets are produced when the electrical potential difference applied between a conductive or partly conductive fluid exiting a capillary and an electrode is not sufficient to overcome the fluid surface tension to form a Taylor cone.

Electrospray Ionization Mass Spectrometry: Fundamentals, Instrumentation, and Applications, edited by R. B. Cole, ISBN 0-471-14564-5, John Wiley & Sons, Inc., New York summarizes much of the fundamental studies of electrospray. Several mathematical models have been generated to explain the principals governing electrospray. Equation 1 defines the electric field E_{c} at the tip of a capillary of radius r_{c} with an applied voltage V_{c} at a distance d from a counter electrode held at ground potential:

$${E}_{c} = \frac{2 {V}_{c}}{{r}_{c} ln ( 4 d / {r}_{c} )} \qquad ( 1 )$$

The electric field Eₒₙ required for the formation of a Taylor cone and liquid jet of a fluid flowing to the tip of this capillary is approximated as:

$${E}_{on} \approx {( \frac{2 γ cos θ}{{ϵ}_{o} {r}_{c}} )}^{1 / 2} \qquad ( 2 )$$

where γ is the surface tension of the fluid, θ is the half-angle of the Taylor cone and ε₀ is the permittivity of vacuum. Equation 3 is derived by combining equations 1 and 2 and approximates the onset voltage Vₒₙ required to initiate an electrospray of a fluid from a capillary:

$${V}_{on} \approx {( \frac{{r}_{c} γ cos θ}{2 {ϵ}_{0}} )}^{1 / 2} ln ( 4 d / {r}_{c} ) \qquad ( 3 )$$

As can be seen by examination of equation 3, the required onset voltage is more dependent on the capillary radius than the distance from the counter-electrode.

It would be desirable to define an electrospray device that could form a stable electrospray of all fluids commonly used in CE, CEC, and LC. The surface tension of solvents commonly used as the mobile phase for these separations range from 100% aqueous (γ=0.073 N/m) to 100% methanol (γ=0.0226 N/m). As the surface tension of the electrospray fluid increases, a higher onset voltage is required to initiate an electrospray for a fixed capillary diameter. As an example, a capillary with a tip diameter of 14 μm is required to electrospray 100% aqueous solutions with an onset voltage of 1000 V. The work of M. S. Wilm et al., Int. J. Mass Spectrom. Ion Processes 136:167-80 (1994), first demonstrates nanoelectrospray from a fused-silica capillary pulled to an outer diameter of 5 μm at a flow rate of 25 nL/min. Specifically, a nanoelectrospray at 25 nL/min was achieved from a 2 μm inner diameter and 5 μm outer diameter pulled fused-silica capillary with 600-700 V at a distance of 1-2 mm from the ion-sampling orifice of an electrospray equipped mass spectrometer.

Electrospray in front of an ion-sampling orifice of an API mass spectrometer produces a quantitative response from the mass spectrometer detector due to the analyte molecules present in the liquid flowing from the capillary. One advantage of electrospray is that the response for an analyte measured by the mass spectrometer detector is dependent on the concentration of the analyte in the fluid and independent of the fluid flow rate. The response of an analyte in solution at a given concentration would be comparable using electrospray combined with mass spectrometry at a flow rate of 100 μL/min compared to a flow rate of 100 nL/min. D. C. Gale et al., Rapid Commun. Mass Spectrom. 7:1017 (1993) demonstrate that higher electrospray sensitivity is achieved at lower flow rates due to increased analyte ionization efficiency. Thus by performing electrospray on a fluid at flow rates in the nanoliter per minute range provides the best sensitivity for an analyte contained within the fluid when combined with mass spectrometry.

Thus, it is desirable to provide an electrospray device for integration of microchip-based separation devices with API-MS instruments. This integration places a restriction on the capillary tip defining a nozzle on a microchip. This nozzle will, in all embodiments, exist in a planar or near planar geometry with respect to the substrate defining the separation device and/or the electrospray device. When this co-planar or near planar geometry exists, the electric field lines emanating from the tip of the nozzle will not be enhanced if the electric field around the nozzle is not defined and controlled and, therefore, an electrospray is only achievable with the application of relatively high voltages applied to the fluid.

Attempts have been made to manufacture an electrospray device for microchip-based separations. Ramsey et al., Anal. Chem. 69:1174-78 (1997) describes a microchip-based separations device coupled with an electrospray mass spectrometer. Previous work from this research group including Jacobson et al., Anal. Chem. 66:1114-18 (1994) and Jacobson et al., Anal. Chem. 66:2369-73 (1994) demonstrate impressive separations using on-chip fluorescence detection. This more recent work demonstrates nanoelectrospray at 90 nL/min from the edge of a planar glass microchip. The microchip-based separation channel has dimensions of 10 μm deep, 60 μm wide, and 33 mm in length. Electro osmotic flow is used to generate fluid flow at 90 nL/min. Application of 4,800 V to the fluid exiting the separation channel on the edge of the microchip at a distance of 3-5 mm from the ion-sampling orifice of an API mass spectrometer generates an electrospray. Approximately 12 nL of the sample fluid collects at the edge of the microchip before the formation of a Taylor cone and stable nanoelectrospray from the edge of the microchip. The volume of this microchip-based separation channel is 19.8 nL. Nanoelectrospray from the edge of this microchip device after capillary electrophoresis or capillary electrochromatography separation is rendered impractical since this system has a dead-volume approaching 60% of the column (channel) volume. Furthermore, because this device provides a flat surface, and, thus, a relatively small amount of physical asperity for the formation of the electrospray, the device requires an impractically high voltage to overcome the fluid surface tension to initiate an electrospray.

Xue, Q. et al., Anal. Chem. 69:426-30 (1997) also describes a stable nanoelectrospray from the edge of a planar glass microchip with a closed channel 25 μm deep, 60 μm wide, and 35-50 mm in length. An electrospray is formed by applying 4,200 V to the fluid exiting the separation channel on the edge of the microchip at a distance of 3-8 mm from the ion-sampling orifice of an API mass spectrometer. A syringe pump is utilized to deliver the sample fluid to the glass microchip at a flow rate of 100 to 200 nL/min. The edge of the glass microchip is treated with a hydrophobic coating to alleviate some of the difficulties associated with nanoelectrospray from a flat surface that slightly improves the stability of the nanoelectrospray. Nevertheless, the volume of the Taylor cone on the edge of the microchip is too large relative to the volume of the separation channel, making this method of electrospray directly from the edge of a microchip impracticable when combined with a chromatographic separation device.

T. D. Lee et. al., 1997 International Conference on Solid-State Sensors and Actuators Chicago, pp. 927-30 (Jun. 16-19, 1997) describes a multi-step process to generate a nozzle on the edge of a silicon microchip 1-3 μm in diameter or width and 40 μm in length and applying 4,000 V to the entire microchip at a distance of 0.25-0.4 mm from the ion-sampling orifice of an API mass spectrometer. Because a relatively high voltage is required to form an electrospray with the nozzle positioned in very close proximity to the mass spectrometer ion-sampling orifice, this device produces an inefficient electrospray that does not allow for sufficient droplet evaporation before the ions enter the orifice. The extension of the nozzle from the edge of the microchip also exposes the nozzle to accidental breakage. More recently, T. D. Lee et. al., in 1999 Twelfth IEEE International Micro Electro Mechanical Systems Conference (Jan. 17-21, 1999), presented this same concept where the electrospray component was fabricated to extend 2.5 mm beyond the edge of the microchip to overcome this phenomenon of poor electric field control within the proximity of a surface.

Thus, it is also desirable to provide an electrospray device with controllable spraying and a method for producing such a device that is easily reproducible and manufacturable in high volumes.

U.S. Pat. No. 5,501,893 to Laermer et. al., reports a method of anisotropic plasma etching of silicon (Bosch process) that provides a method of producing deep vertical structures that is easily reproducible and controllable. This method of anisotropic plasma etching of silicon incorporates a two step process. Step one is an anisotropic etch step using a reactive ion etching (RIE) gas plasma of sulfur hexafluoride (SF₆). Step two is a passivation step that deposits a polymer on the vertical surfaces of the silicon substrate. This polymerizing step provides an etch stop on the vertical surface that was exposed in step one. This two step cycle of etch and passivation is repeated until the depth of the desired structure is achieved. This method of anisotropic plasma etching provides etch rates over 3 μm/min of silicon depending on the size of the feature being etched. The process also provides selectivity to etching silicon versus silicon dioxide or resist of greater than 100:1 which is important when deep silicon structures are desired. Laermer et. al., in 1999 Twelfth IEEE International Micro Electro Mechanical Systems Conference (Jan. 17-21, 1999), reported improvements to the Bosch process. These improvements include silicon etch rates approaching 10 μm/min, selectivity exceeding 300:1 to silicon dioxide masks, and more uniform etch rates for features that vary in size.

The present invention is directed toward a novel utilization and sequencing of steps to fabricate microchip-based electrospray systems.

### SUMMARY OF THE INVENTION

An aspect of the present invention is directed to a method for fabricating a nozzle on a substrate including:

a) providing a substrate;

b) forming at least one channel in the substrate;

c) backgrinding the substrate to create at least one through channel;

d) forming an annulus at the surface of the substrate around the at least one through channel opening to form a nozzle; and

e) cutting the substrate into a plurality of sections, at least one section including at least one through channel.

Another aspect of the present invention is directed to a method for fabricating a nozzle on a substrate including:

a) providing a substrate;

b) forming at least one channel in the substrate;

c) forming an annulus at the surface of the substrate around the at least one channel opening to form a nozzle;

d) backgrinding the substrate to create at least one through channel; and

e) cutting the substrate into a plurality of sections, at least one section including at least one through channel.

Another method of the present invention is directed to a method for fabricating a nozzle on a substrate including:

a) providing a substrate;

b) forming at least one channel in the substrate;

c) backgrinding the substrate to create at least one through channel;

d) forming an annulus at the surface of the substrate around the at least one through channel opening to form a nozzle;

e) forming a dielectric layer on the surface of the substrate; and

f) cutting the substrate into a plurality of sections, at least one section including at least one through channel.

Another aspect of the present invention is directed to a method for fabricating a nozzle on a substrate including:

a) providing a substrate;

b) forming at least one channel in the substrate;

c) forming an annulus at the surface of the substrate around the at least one channel opening to form a nozzle;

d) backgrinding the substrate to create at least one through channel;

e) forming at least one dielectric layer on the surface of the substrate; and

f) cutting the substrate into a plurality of sections, at least one section including at least one through channel.

### BRIEF DESCRIPTION OF THE DRAWINGS

FIG. 1 is a cross-sectional view of a single-side polished silicon wafer 300.

FIG. 2 is a cross-sectional view of the substrate 300 showing a layer of silicon dioxide 310 on both sides.

FIG. 3, is a cross-sectional view of the substrate 300 showing a film of positive-working photoresist 308 deposited on the silicon dioxide layer 310 on the polished nozzle side of the substrate 300.

FIG. 4 is a cross-sectional view of the substrate 300 showing the film 308 deposited in a pattern corresponding to the entrance to through-wafer channel 304 and an area of photoresist corresponding to the recessed annular region 306.

FIG. 5 is a plan view of the substrate 300 showing a mask used to pattern the shape that will form the nozzle hole 304 and annulus 306 in the completed electrospray device.

FIG. 6 is a cross-sectional view of the substrate 300 showing the exposed areas 304 and 306 of the silicon dioxide layer 310 removed to the silicon substrate 318 and 320.

FIG. 7 is a cross-sectional view of the substrate 300 showing the removal of the remaining photoresist 308.

FIG. 8 is a cross-sectional view of the substrate 300 showing a film of positive-working photoresist 308′ deposited on the silicon dioxide layer 310 on the nozzle side.

FIG. 9 is a cross-sectional view of the substrate 300 after development of the photoresist 308′ and the exposed area 304 of the photoresist removed to the underlying silicon substrate 335.

FIG. 10 is a plan view of the substrate 300 showing a mask pattern of an area of the photoresist corresponding to the entrance to through-wafer channel 336.

FIG. 11 is a cross-sectional view of the substrate 300 showing etching of the through-wafer channel 336 of the nozzle interior.

FIG. 12 is a cross-sectional view of the substrate 300 showing removal of the remaining photoresist 308′.

FIG. 13 is a cross-sectional view of the substrate 300 showing etching of the through-wafer channel 336 of the nozzle interior and annulus 338.

FIG. 14 is a cross-sectional view of the substrate 300 showing the lapp grinding of the back side of the wafer exposing the nozzle channel 336.

FIG. 15 is a cross-sectional view of the substrate 300 showing removal of the remaining silicon oxide 310.

FIG. 16 is a cross-sectional view of the substrate 300 showing a dielectric layer 340 on the surface of the substrate.

### DETAILED DESCRIPTION OF THE INVENTION

The electrospray device of the present invention generally includes a substrate material such as silicon defining a channel between an entrance orifice on an injection surface and a nozzle on an ejection surface (the major surface) such that the electrospray generated by the device is generally perpendicular to the ejection surface. The nozzle has an inner and an outer diameter and is defined by an annular portion recessed from the ejection surface. The recessed annular region extends radially from the outer diameter. The tip of the nozzle is co-planar or level with and does not extend beyond the ejection surface. Thus, the nozzle is protected against accidental breakage. The nozzle, the channel, and the recessed annular region are etched from the silicon substrate by deep reactive-ion etching and other standard semiconductor processing techniques. Fabrication of electrospray devices are disclosed in U.S. patent application Ser. No. 09/468,535, filed Dec. 20, 1999, entitled “Integrated Monolithic Microfabricated Dispensing Nozzle and Liquid Chromatography-Electrospray System and Method” to Schultz et al., and U.S. patent application Ser. No. 09/748,518, filed Dec. 22, 2000, entitled “Multiple Electrospray Device, Systems and Methods” to Schultz et al., which are incorporated herein by reference in their entirety.

All surfaces of the silicon substrate preferably have insulating layers thereon to electrically isolate the liquid sample from the substrate and the ejection and injection surfaces from each other such that different potential voltages may be individually applied to each surface, the silicon substrate and the liquid sample. The insulating layer generally constitutes a silicon dioxide layer combined with a silicon nitride layer. The silicon nitride layer provides a moisture barrier against water and ions from penetrating through to the substrate thus preventing electrical breakdown between a fluid moving in the channel and the substrate. The electrospray apparatus preferably includes at least one controlling electrode electrically contacting the substrate for the application of an electric potential to the substrate.

Preferably, the nozzle, channel and recess are etched from the silicon substrate by reactive-ion etching and other standard semiconductor processing techniques. The injection-side features, through-substrate fluid channel, ejection-side features, and controlling electrodes are formed monolithically from a monocrystalline silicon substrate—i.e., they are formed during the course of and as a result of a fabrication sequence that requires no manipulation or assembly of separate components.

Because the electrospray device is manufactured using reactive-ion etching and other standard semiconductor processing techniques, the dimensions of such a device nozzle can be very small, for example, as small as 2 μm inner diameter and 5 μm outer diameter. Thus, a through-substrate fluid channel having, for example, 5 μm inner diameter and a substrate thickness of 250 μm only has a volume of 4.9 pL (“picoliters”). The micrometer-scale dimensions of the electrospray device minimize the dead volume and thereby increase efficiency and analysis sensitivity when combined with a separation device.

The electrospray device of the present invention provides for the efficient and effective formation of an electrospray. By providing an electrospray surface (i.e., the tip of the nozzle) from which the fluid is ejected with dimensions on the order of micrometers, the device limits the voltage required to generate a Taylor cone and subsequent electrospray. The nozzle of the electrospray device provides the physical asperity on the order of micrometers on which a large electric field is concentrated. Further, the nozzle of the electrospray device contains a thin region of conductive silicon insulated from a fluid moving through the nozzle by the insulating silicon dioxide and silicon nitride layers. The fluid and substrate voltages and the thickness of the insulating layers separating the silicon substrate from the fluid determine the electric field at the tip of the nozzle. Additional electrode(s) on the ejection surface to which electric potential(s) may be applied and controlled independent of the electric potentials of the fluid and the substrate may be incorporated in order to advantageously modify and optimize the electric field in order to focus the gas phase ions produced by the electrospray.

The microchip-based electrospray device of the present invention provides minimal extra-column dispersion as a result of a reduction in the extra-column volume and provides efficient, reproducible, reliable and rugged formation of an electrospray. This electrospray device is perfectly suited as a means of electrospray of fluids from microchip-based separation devices. The design of this electrospray device is also robust such that the device can be readily mass-produced in a cost-effective, high-yielding process.

The electrospray device may be interfaced to or integrated downstream from a sampling device, depending on the particular application. For example, the analyte may be electrosprayed onto a surface to coat that surface or into another device for purposes of conveyance, analysis, and/or synthesis. As described previously, highly charged droplets are formed at atmospheric pressure by the electrospray device from nanoliter-scale volumes of an analyte. The highly charged droplets produce gas-phase ions upon sufficient evaporation of solvent molecules which may be sampled, for example, through an ion-sampling orifice of an atmospheric pressure ionization mass spectrometer (“API-MS”) for analysis of the electrosprayed fluid.

A multi-system chip thus provides a rapid sequential chemical analysis system fabricated using Micro-ElectroMechanical System (“MEMS”) technology. The multi-system chip enables automated, sequential separation and injection of a multiplicity of samples, resulting in significantly greater analysis throughput and utilization of the mass spectrometer instrument for high-throughput detection of compounds for drug discovery.

Another aspect of the present invention provides a silicon microchip-based electrospray device for producing electrospray of a liquid sample. The electrospray device may be interfaced downstream to an atmospheric pressure ionization mass spectrometer (“API-MS”) for analysis of the electrosprayed fluid.

The use of multiple nozzles for electrospray of fluid from the same fluid stream extends the useful flow rate range of microchip-based electrospray devices. Thus, fluids may be introduced to the multiple electrospray device at higher flow rates as the total fluid flow is split between all of the nozzles. For example, by using 10 nozzles per fluid channel, the total flow can be 10 times higher than when using only one nozzle per fluid channel. Likewise, by using 100 nozzles per fluid channel, the total flow can be 100 times higher than when using only one nozzle per fluid channel. The fabrication methods used to form these electrospray nozzles allow for multiple nozzles to be easily combined with a single fluid stream channel greatly extending the useful fluid flow rate range and increasing the mass spectral sensitivity for microfluidic devices.

The present nozzle system is fabricated using Micro-ElectroMechanical System (“MEMS”) fabrication technologies designed to micromachine 3-dimensional features from a silicon substrate. MEMS technology, in particular, deep reactive ion etching (“DRIE”), enables etching of the small vertical features required for the formation of micrometer dimension surfaces in the form of a nozzle for successful nanoelectrospray of fluids. Insulating layers of silicon dioxide and silicon nitride are also used for independent application of an electric field surrounding the nozzle, preferably by application of a potential voltage to a fluid flowing through the silicon device and a potential voltage applied to the silicon substrate. This independent application of a potential voltage to a fluid exiting the nozzle tip and the silicon substrate creates a high electric field, on the order of 108 V/m, at the tip of the nozzle. This high electric field at the nozzle tip causes the formation of a Taylor cone, fluidic jet and highly-charged fluidic droplets characteristic of the electrospray of fluids. These two voltages, the fluid voltage and the substrate voltage, control the formation of a stable electrospray from this microchip-based electrospray device.

The electrical properties of silicon and silicon-based materials are well characterized. The use of silicon dioxide and silicon nitride layers grown or deposited on the surfaces of a silicon substrate are well known to provide electrical insulating properties. Incorporating silicon dioxide and silicon nitride layers in a monolithic silicon electrospray device with a defined nozzle provides for the enhancement of an electric field in and around features etched from a monolithic silicon substrate. This is accomplished by independent application of a voltage to the fluid exiting the nozzle and the region surrounding the nozzle. Silicon dioxide layers may be grown thermally in an oven to a desired thickness. Silicon nitride can be deposited using low pressure chemical vapor deposition (“LPCVD”). Metals may be further vapor deposited on these surfaces to provide for application of a potential voltage on the surface of the device. Both silicon dioxide and silicon nitride function as electrical insulators allowing the application of a potential voltage to the substrate that is different than that applied to the surface of the device. An important feature of a silicon nitride layer is that it provides a moisture barrier between the silicon substrate, silicon dioxide and any fluid sample that comes in contact with the device. Silicon nitride prevents water and ions from diffusing through the silicon dioxide layer to the silicon substrate which may cause an electrical breakdown between the fluid and the silicon substrate. Additional layers of silicon dioxide, metals and other materials may further be deposited on the silicon nitride layer to provide chemical functionality to silicon-based devices.

The nozzle or ejection side of the device and the reservoir or injection side of the device are connected by the through-wafer channels thus creating a fluidic path through the silicon substrate.

Fluids may be introduced to this microfabricated electrospray device by a fluid delivery device such as a probe, conduit, capillary, micropipette, microchip, or the like. A probe moves into contact with the injection or reservoir side of the electrospray device of the present invention. The probe can have a disposable tip. The fluid probe can have a seal, for example an o-ring, at the tip to form a seal between the probe tip and the injection surface of the substrate. Any array of a plurality of electrospray devices can be fabricated on a monolithic substrate. One liquid sample handling device is shown for clarity, however, multiple liquid sampling devices can be utilized to provide one or more fluid samples to one or more electrospray devices in accordance with the present invention. The fluid probe and the substrate can be manipulated in 3-dimensions for staging of, for example, different devices in front of a mass spectrometer or other sample detection apparatus.

To generate an electrospray, fluid may be delivered to the through-substrate channel of the electrospray device by, for example, a capillary, micropipette or microchip. The fluid is subjected to a potential voltage, for example, in the capillary or in the reservoir or via an electrode provided on the reservoir surface and isolated from the surrounding surface region and the substrate. A potential voltage may also be applied to the silicon substrate via the electrode on the edge of the silicon substrate the magnitude of which is preferably adjustable for optimization of the electrospray characteristics. The fluid flows through the channel and exits from the nozzle in the form of a Taylor cone, liquid jet, and very fine, highly charged fluidic droplets.

The nozzle provides the physical asperity to promote the formation of a Taylor cone and efficient electrospray of a fluid. The nozzle also forms a continuation of and serves as an exit orifice of the through-wafer channel. The recessed annular region serves to physically isolate the nozzle from the surface. The present invention allows the optimization of the electric field lines emanating from the fluid exiting the nozzle, for example, through independent control of the potential voltage of the fluid and the potential voltage of the substrate.

The electric field at the nozzle tip can be simulated using SIMION™ ion optics software. SIMION™ allows for the simulation of electric field lines for a defined array of electrodes. For example, in a 20 ∥m diameter nozzle with a nozzle height of 50 μm fluid flowing through the nozzle and exiting the nozzle tip in the shape of a hemisphere has a potential voltage of 1000 V. The substrate has a potential voltage of zero volts. A simulated third electrode is located 5 mm from the nozzle side of the substrate and has a potential voltage of zero volts. This third electrode is generally an ion-sampling orifice of an atmospheric pressure ionization mass spectrometer. This simulates the electric field required for the formation of a Taylor cone rather than the electric field required to maintain an electrospray. The simulated electric field at the fluid tip with these dimensions and potential voltages is 8.2×10⁷ V/m. For a nozzle with a fluid potential voltage of 1000 V, substrate voltage of zero V and a third electrode voltage of 800 V the electric field at the nozzle tip is 8.0×10⁷ V/m indicating that the applied voltage of this third electrode has little effect on the electric field at the nozzle tip. For the same nozzle with a fluid potential voltage of 1000 V, substrate voltage of 800 V and a third electrode voltage of 0 V, the electric field at the nozzle tip is reduced significantly to a value of 2.2×10⁷ V/m. This indicates that very fine control of the electric field at the nozzle tip is achieved with this invention by independent control of the applied fluid and substrate voltages and is relatively insensitive to other electrodes placed up to 5 mm from the device. This level of control of the electric field at the nozzle tip is of significant importance for electrospray of fluids from a nozzle co-planar with the surface of a substrate.

This fine control of the electric field allows for precise control of the electrospray of fluids from these nozzles. When electrospraying fluids from this invention, this fine control of the electric field allows for a controlled formation of multiple Taylor cones and electrospray plumes from a single nozzle. By simply increasing the fluid voltage while maintaining the substrate voltage at zero V, the number of electrospray plumes emanating from one nozzle can be stepped from one to four.

The high electric field at the nozzle tip applies a force to ions contained within the fluid exiting the nozzle. This force pushes positively-charged ions to the fluid surface when a positive voltage is applied to the fluid relative to the substrate potential voltage. Due to the repulsive force of likely-charged ions, the surface area of the Taylor cone generally defines and limits the total number of ions that can reside on the fluidic surface. It is generally believed that, for electrospray, a gas phase ion for an analyte can most easily be formed by that analyte when it resides on the surface of the fluid. The total surface area of the fluid increases as the number of Taylor cones at the nozzle tip increases resulting in the increase in solution phase ions at the surface of the fluid prior to electrospray formation. The ion intensity will increase as measured by the mass spectrometer when the number of electrospray plumes increase as shown in the example above.

Another important feature of the present invention is that since the electric field around each nozzle is preferably defined by the fluid and substrate voltage at the nozzle tip, multiple nozzles can be located in close proximity, on the order of tens of microns. This novel feature of the present invention allows for the formation of multiple electrospray plumes from multiple nozzles of a single fluid stream thus greatly increasing the electrospray sensitivity available for microchip-based electrospray devices. Multiple nozzles of an electrospray device in fluid communication with one another not only improve sensitivity but also increase the flow rate capabilities of the device. For example, the flow rate of a single fluid stream through one nozzle having the dimensions of a 10 micron inner diameter, 20 micron outer diameter, and a 50 micron length is about 1 μL/min.; and the flow rate through 200 of such nozzles is about 200 μL/min. Accordingly, devices can be fabricated having the capacity for flow rates up to about 2 μL/min., from about 2 μL/min. to about 1 mL/min., from about 100 nL/min. to about 500 nL/min., and greater than about 2 μL/min. possible.

Arrays of multiple electrospray devices having any nozzle number and format may be fabricated according to the present invention. The electrospray devices can be positioned to form from a low-density array to a high-density array of devices. Arrays can be provided having a spacing between adjacent devices of 9 mm, 4.5 mm, 2.25 mm, 1.12 mm, 0.56 mm, 0.28 mm, and smaller to a spacing as close as about 50 μm apart, respectively, which correspond to spacing used in commercial instrumentation for liquid handling or accepting samples from electrospray systems. Similarly, systems of electrospray devices can be fabricated in an array having a device density exceeding about 5 devices/cm², exceeding about 16 devices/cm², exceeding about 30 devices/cm², and exceeding about 81 devices/cm², preferably from about 30 devices/cm² to about 100 devices/cm².

Dimensions of the electrospray device can be determined according to various factors such as the specific application, the layout design as well as the upstream and/or downstream device to which the electrospray device is interfaced or integrated. Further, the dimensions of the channel and nozzle may be optimized for the desired flow rate of the fluid sample. The use of reactive-ion etching techniques allows for the reproducible and cost effective production of small diameter nozzles, for example, a 2 μm inner diameter and 5 μm outer diameter. Such nozzles can be fabricated as close as 20 μm apart, providing a density of up to about 160,000 nozzles/cm². Nozzle densities up to about 10,000/cm², up to about 15,625/cm², up to about 27,566/cm², and up to about 40,000/cm², respectively, can be provided within an electrospray device. Similarly, nozzles can be provided wherein the spacing on the ejection surface between the centers of adjacent exit orifices of the spray units is less than about 500 μm, less than about 200 μm, less than about 100 μm, and less than about 50 μm, respectively. For example, an electrospray device having one nozzle with an outer diameter of 20 μm would respectively have a surrounding sample well 30 μm wide. A densely packed array of such nozzles could be spaced as close as 50 μm apart as measured from the nozzle center.

In one currently preferred embodiment, the silicon substrate of the electrospray device is approximately 250-500 μm in thickness and the cross-sectional area of the through-substrate channel is less than approximately 2,500 μm². Where the channel has a circular cross-sectional shape, the channel and the nozzle have an inner diameter of up to 50 μm, more preferably up to 30 μm; the nozzle has an outer diameter of up to 60 μm, more preferably up to 40 μm; and nozzle has a height of (and the annular region has a depth of) up to 100 μm. The recessed portion preferably extends up to 300 μm outwardly from the nozzle. The silicon dioxide layer has a thickness of approximately 1-4 μm, preferably 1-3 μm. The silicon nitride layer has a thickness of approximately less than 2 μm.

Furthermore, the electrospray device may be operated to produce larger, minimally-charged droplets. This is accomplished by decreasing the electric field at the nozzle exit to a value less than that required to generate an electrospray of a given fluid. Adjusting the ratio of the potential voltage of the fluid and the potential voltage of the substrate controls the electric field. A fluid to substrate potential voltage ratio approximately less than 2 is preferred for droplet formation. The droplet diameter in this mode of operation is controlled by the fluid surface tension, applied voltages and distance to a droplet receiving well or plate. This mode of operation is ideally suited for conveyance and/or apportionment of a multiplicity of discrete amounts of fluids, and may find use in such devices as ink jet printers and equipment and instruments requiring controlled distribution of fluids.

The electrospray device of the present invention includes a silicon substrate material defining a channel between an entrance orifice on a reservoir surface and a nozzle on a nozzle surface such that the electrospray generated by the device is generally perpendicular to the nozzle surface. The nozzle has an inner and an outer diameter and is defined by an annular portion recessed from the surface. The recessed annular region extends radially from the nozzle outer diameter. The tip of the nozzle is co-planar or level with and preferably does not extend beyond the substrate surface. In this manner the nozzle can be protected against accidental breakage. The nozzle, channel, reservoir and the recessed annular region are etched from the silicon substrate by reactive-ion etching and other standard semiconductor processing techniques.

All surfaces of the silicon substrate preferably have insulating layers to electrically isolate the liquid sample from the substrate such that different potential voltages may be individually applied to the substrate and the liquid sample. The insulating layers can constitute a silicon dioxide layer combined with a silicon nitride layer. The silicon nitride layer provides a moisture barrier against water and ions from penetrating through to the substrate causing electrical breakdown between a fluid moving in the channel and the substrate. The electrospray apparatus preferably includes at least one controlling electrode electrically contacting the substrate for the application of an electric potential to the substrate.

Preferably, the nozzle, channel and recess are etched from the silicon substrate by reactive-ion etching and other standard semiconductor processing techniques. The nozzle side features, through-substrate fluid channel, reservoir side features, and controlling electrodes are preferably formed monolithically from a monocrystalline silicon substrate—i.e., they are formed during the course of and as a result of a fabrication sequence that requires no manipulation or assembly of separate components.

Because the electrospray device is manufactured using reactive-ion etching and other standard semiconductor processing techniques, the dimensions of such a device can be very small, for example, as small as 2 μm inner diameter and 5 μm outer diameter. Thus, a through-substrate fluid channel having, for example, 5 μm inner diameter and a substrate thickness of 250 μm only has a volume of 4.9 pL. The micrometer-scale dimensions of the electrospray device minimize the dead volume and thereby increase efficiency and analysis sensitivity when combined with a separation device.

The electrospray device of the present invention provides for the efficient and effective formation of an electrospray. By providing an electrospray surface from which the fluid is ejected with dimensions on the order of micrometers, the electrospray device limits the voltage required to generate a Taylor cone as the voltage is dependent upon the nozzle diameter, the surface tension of the fluid, and the distance of the nozzle from an extracting electrode. The nozzle of the electrospray device provides the physical asperity on the order of micrometers on which a large electric field is concentrated. Further, the electrospray device may provide additional electrode(s) on the ejecting surface to which electric potential(s) may be applied and controlled independent of the electric potentials of the fluid and the extracting electrode in order to advantageously modify and optimize the electric field in order to focus the gas phase ions resulting from electrospray of fluids. The combination of the nozzle and the additional electrode(s) thus enhance the electric field between the nozzle, the substrate and the extracting electrode. The electrodes are preferable positioned within about 500 microns, and more preferably within about 200 microns from the exit orifice.

The microchip-based electrospray device of the present invention provides minimal extra-column dispersion as a result of a reduction in the extra-column volume and provides efficient, reproducible, reliable and rugged formation of an electrospray. This electrospray device is perfectly suited as a means of electrospray of fluids from microchip-based separation devices. The design of this electrospray device is also robust such that the device can be readily mass-produced in a cost-effective, high-yielding process.

In operation, a conductive or partly conductive liquid sample is introduced into the through-substrate channel entrance orifice on the injection surface. The liquid is held at a potential voltage, either by means of a conductive fluid delivery device to the electrospray device or by means of an electrode formed on the injection surface isolated from the surrounding surface region and from the substrate. The electric field strength at the tip of the nozzle is enhanced by the application of a voltage to the substrate and/or the ejection surface, preferably zero volts up to approximately less than one-half of the voltage applied to the fluid. Thus, by the independent control of the fluid/nozzle and substrate/ejection surface voltages, the electrospray device of the present invention allows the optimization of the electric field emanating from the nozzle. The electrospray device of the present invention may be placed 1-2 mm or up to 10 mm from the orifice of an atmospheric pressure ionization (“API”) mass spectrometer to establish a stable nanoelectrospray at flow rates in the range of a few nanoliters per minute.

The electrospray device may be interfaced or integrated downstream to a sampling device, depending on the particular application. For example, the analyte may be electrosprayed onto a surface to coat that surface or into another device for purposes of conveyance, analysis, and/or synthesis. As described above, highly charged droplets are formed at atmospheric pressure by the electrospray device from nanoliter-scale volumes of an analyte. The highly charged droplets produce gas-phase ions upon sufficient evaporation of solvent molecules which may be sampled, for example, through an ion-sampling orifice of an atmospheric pressure ionization mass spectrometer (“API-MS”) for analysis of the electrosprayed fluid.

One embodiment of the present invention is in the form of an array of multiple electrospray devices which allows for massive parallel processing. The multiple electrospray devices or systems fabricated by massively parallel processing on a single wafer may then be cut or otherwise separated into multiple devices or systems.

The electrospray device may also serve to reproducibly distribute and deposit a sample from a mother plate to daughter plate(s) by nanoelectrospray deposition or by the droplet method. A chip-based combinatorial chemistry system including a reaction well block may define an array of reservoirs for containing the reaction products from a combinatorially synthesized compound. The reaction well block further defines channels, nozzles and recessed portions such that the fluid in each reservoir may flow through a corresponding channel and exit through a corresponding nozzle in the form of droplets. The reaction well block may define any number of reservoir(s) in any desirable configuration, each reservoir being of a suitable dimension and shape. The volume of a reservoir may range from a few picoliters up to several microliters.

The reaction well block may serve as a mother plate to interface to a microchip-based chemical synthesis apparatus such that the droplet method of the electrospray device may be utilized to reproducibly distribute discreet quantities of the product solutions to a receiving or daughter plate. The daughter plate defines receiving wells that correspond to each of the reservoirs. The distributed product solutions in the daughter plate may then be utilized to screen the combinatorial chemical library against biological targets.

The electrospray device may also serve to reproducibly distribute and deposit an array of samples from a mother plate to daughter plates, for example, for proteomic screening of new drug candidates. This may be by either droplet formation or electrospray modes of operation. Electrospray device(s) may be etched into a microdevice capable of synthesizing combinatorial chemical libraries. At a desired time, a nozzle(s) may apportion a desired amount of a sample(s) or reagent(s) from a mother plate to a daughter plate(s). Control of the nozzle dimensions, applied voltages, and time provide a precise and reproducible method of sample apportionment or deposition from an array of nozzles, such as for the generation of sample plates for molecular weight determinations by matrix-assisted laser desorption/ionization time-of-flight mass spectrometry (“MALDI-TOFMS”). The capability of transferring analytes from a mother plate to daughter plates may also be utilized to make other daughter plates for other types of assays, such as proteomic screening. The fluid to substrate potential voltage ratio can be chosen for formation of an electrospray or droplet mode based on a particular application.

An array of multiple electrospray devices can be configured to disperse ink for use in an ink jet printer. The control and enhancement of the electric field at the exit of the nozzles on a substrate will allow for a variation of ink apportionment schemes including the formation of droplets approximately two times the nozzle diameters or of submicometer, highly-charged droplets for blending of different colors of ink.

The electrospray device of the present invention can be integrated with miniaturized liquid sample handling devices for efficient electrospray of the liquid samples for detection using a mass spectrometer. The electrospray device may also be used to distribute and apportion fluid samples for use with high-throughput screen technology. The electrospray device may be chip-to-chip or wafer-to-wafer bonded to plastic, glass, or silicon microchip-based liquid separation devices capable of, for example, capillary electrophoresis, capillary electrochromatography, affinity chromatography, liquid chromatography (“LC”), or any other condensed-phase separation technique.

An array or matrix of multiple electrospray devices of the present invention may be manufactured on a single microchip as silicon fabrication using standard, well-controlled thin-film processes. This not only eliminates handling of such micro components but also allows for rapid parallel processing of functionally similar elements. The low cost of these electrospray devices allows for one-time use such that cross-contamination from different liquid samples may be eliminated.

A multi-system chip thus provides a rapid sequential chemical analysis system fabricated using Micro-ElectroMechanical System (“MEMS”) technology. For example, the multi-system chip enables automated, sequential separation and injection of a multiplicity of samples, resulting in significantly greater analysis throughput and utilization of the mass spectrometer instrument for, for example, high-throughput detection of compounds for drug discovery.

Another aspect of the present invention provides a silicon microchip-based electrospray device for producing electrospray of a liquid sample. The electrospray device may be interfaced downstream to an atmospheric pressure ionization mass spectrometer (“API-MS”) for analysis of the electrosprayed fluid. Another aspect of the invention is an integrated miniaturized liquid phase separation device, which may have, for example, glass, plastic or silicon substrates integral with the electrospray device.

The electrospray device is preferably fabricated as a monolithic silicon substrate utilizing well-established, controlled thin-film silicon processing techniques such as thermal oxidation, photolithography, reactive-ion etching (RIE), chemical vapor deposition, ion implantation, and metal deposition. Fabrication using such silicon processing techniques facilitates massively parallel processing of similar devices, is time- and cost-efficient, allows for tighter control of critical dimensions, is easily reproducible, and results in a wholly integral device, thereby eliminating any assembly requirements. Further, the fabrication sequence may be easily extended to create physical aspects or features on the injection surface and/or ejection surface of the electrospray device to facilitate interfacing and connection to a fluid delivery system or to facilitate integration with a fluid delivery sub-system to create a single integrated system.

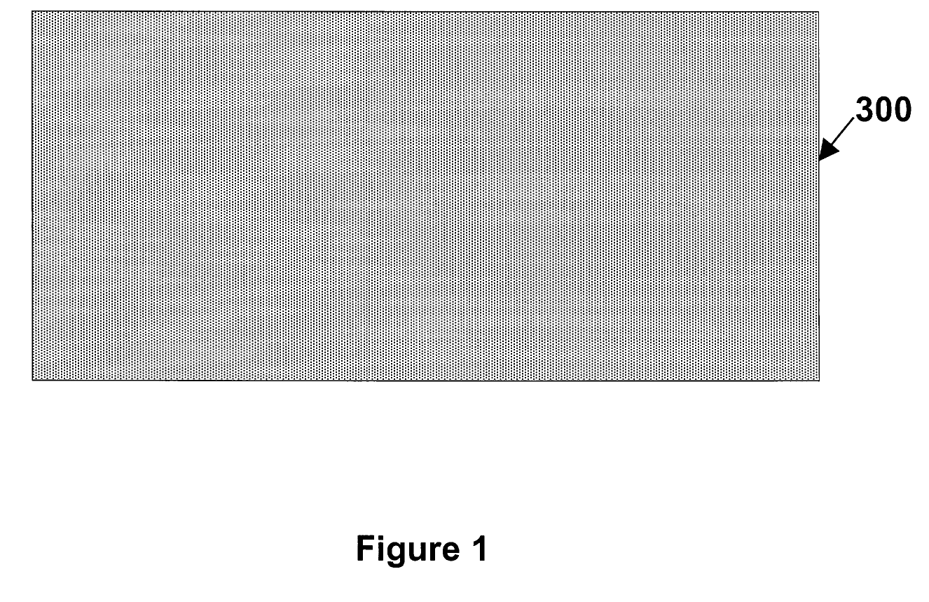

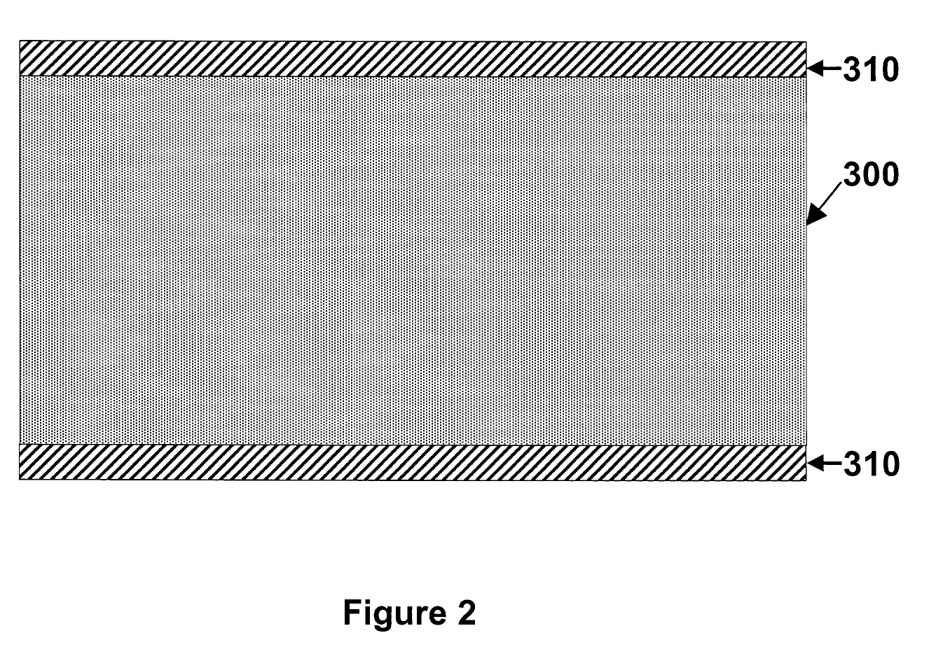

FIGS. 1-16 illustrate the processing steps for fabricating the electrospray device of the present invention. The sequence of the steps may be adjusted depending upon the desired procedure. FIG. 1 is a cross-sectional view of a single-side polished silicon wafer 300. The wafer is cleaned and coated with a hard mask such as silicon dioxide. For example, a hard mask can be grown at an elevated temperature in an oxidizing environment to form a layer or film of silicon dioxide 310 on both sides of the substrate 300, as shown in FIG. 2. Each of the resulting silicon dioxide layers 310 has a thickness of approximately 0.5-3 μm. The silicon dioxide layers 310 serve as masks for subsequent selective etching of certain areas of the silicon substrate 300.

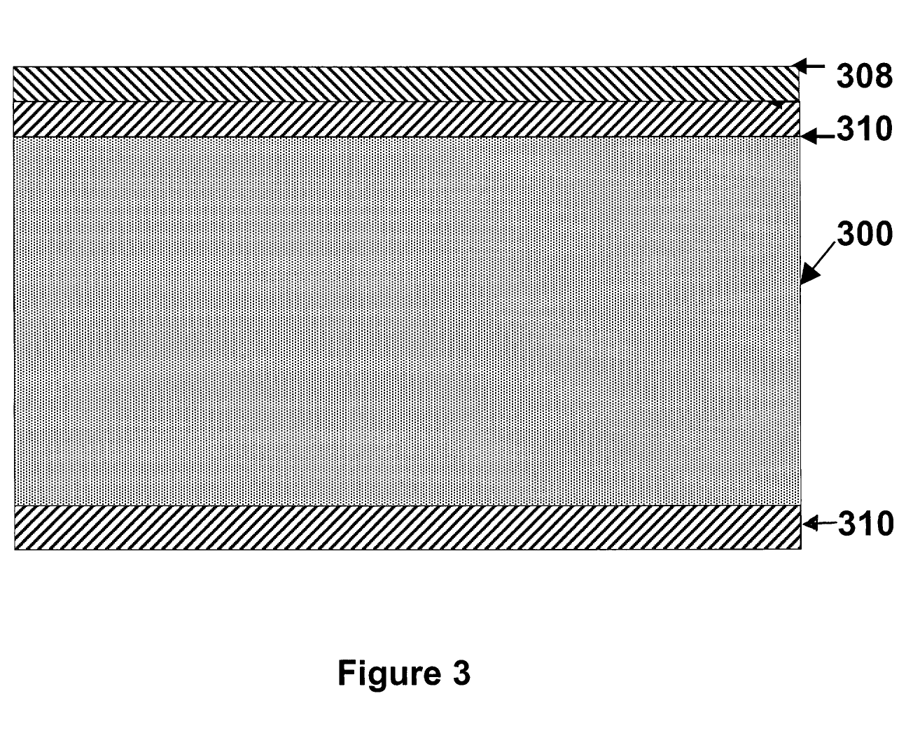

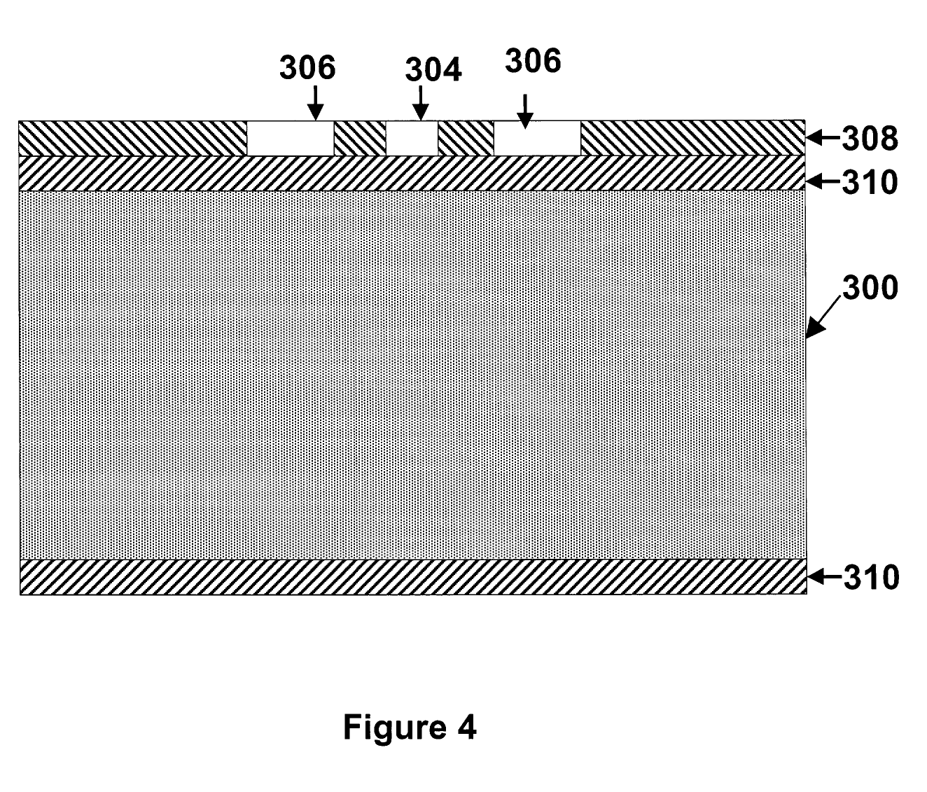

Referring to FIG. 3, a soft mask, such as a film of positive-working photoresist 308, is deposited on the silicon dioxide layer 310 on the polished nozzle side of the substrate 300. The film 308 is deposited in a pattern corresponding to the entrance to through-wafer channel 304 and an area of photoresist corresponding to the recessed annular region 306 which will be subsequently etched is selectively exposed through a mask, as shown in FIG. 4, by an optical lithographic exposure tool passing short-wavelength light, such as blue or near-ultraviolet at wavelengths of 365, 405, or 436 nanometers.

As shown in the cross-sectional view of FIG. 4, after development of the photoresist 308, the exposed area 304 of the photoresist is removed and open to the underlying silicon dioxide layer and the exposed area 306 of the photoresist is removed and open to the underlying silicon dioxide layer, while the unexposed areas remain protected by photoresist 308.

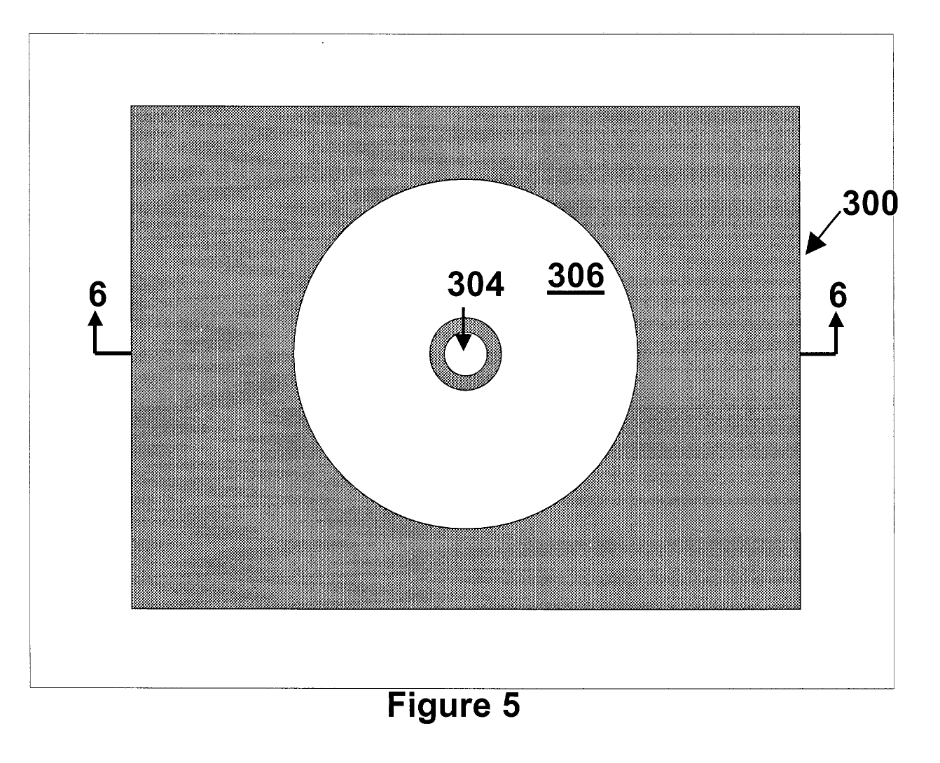

Referring to the plan view of FIG. 5, a hard mask is used to pattern the shape that will form the nozzle hole 304 and annulus 306 in the completed electrospray device 300. The patterns in the form of circles 304 and 306 form a through-wafer channel and a recessed annular space around the nozzle of a completed electrospray device.

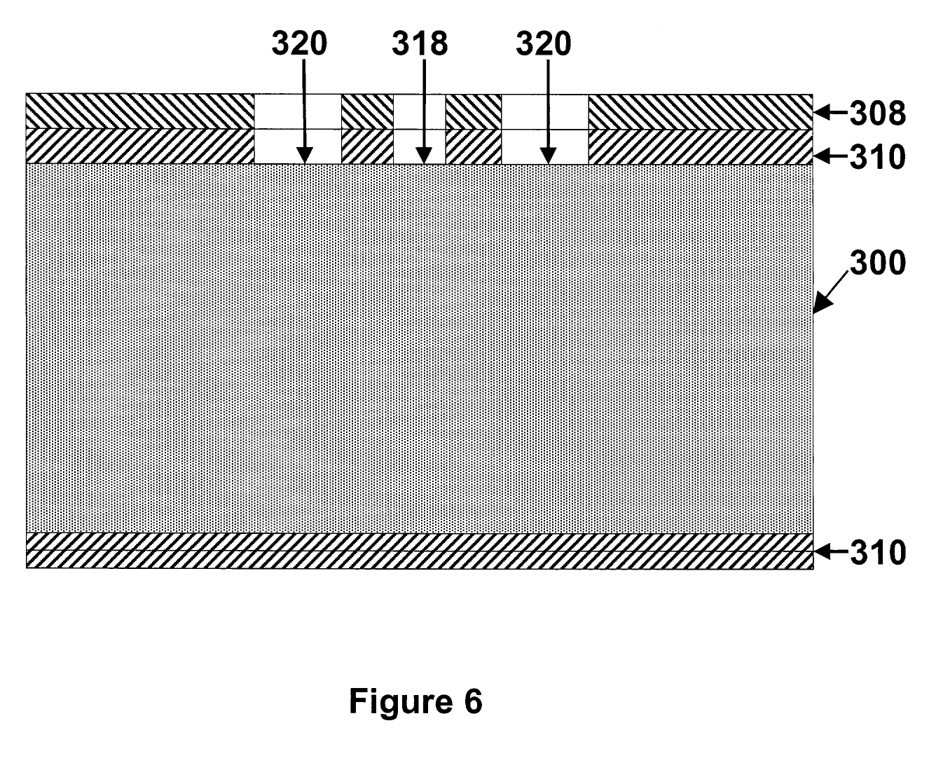

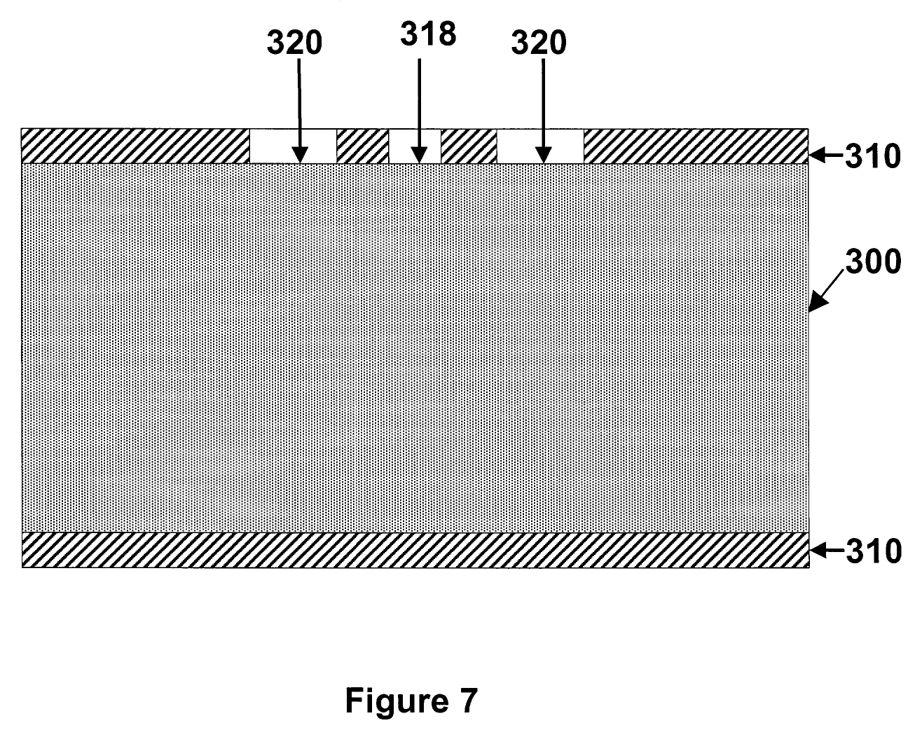

Referring to FIG. 6, the exposed areas 304 and 306 of the silicon dioxide layer 310 is then etched by a fluorine-based plasma with a high degree of anisotropy and selectivity to the protective photoresist 308 until the silicon substrate 318 and 320 are reached. As shown in the cross-sectional view of FIG. 7, the remaining photoresist 308 is removed from the silicon substrate 300.

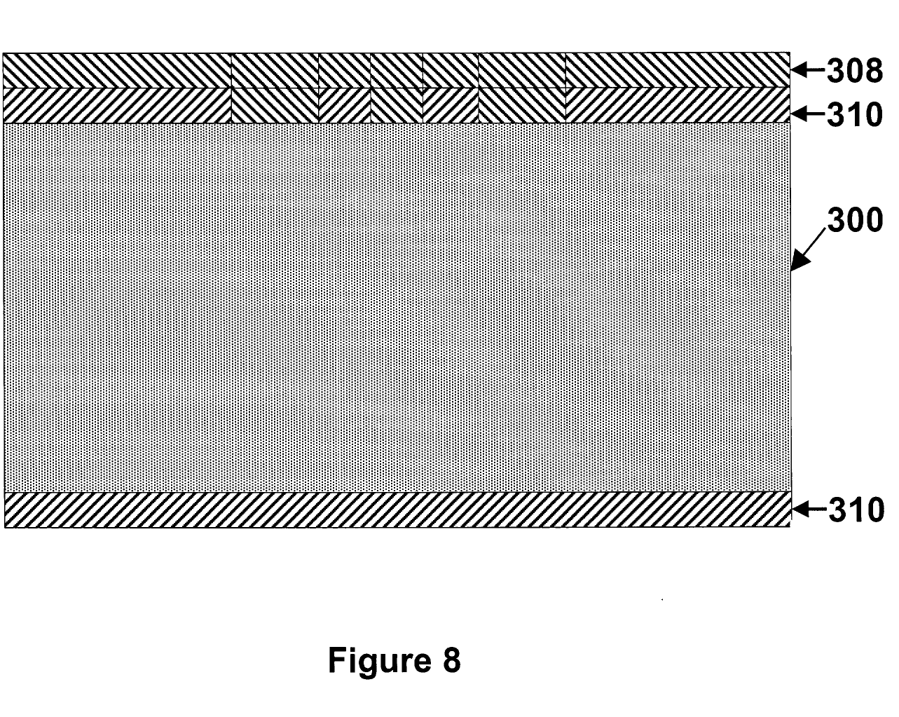

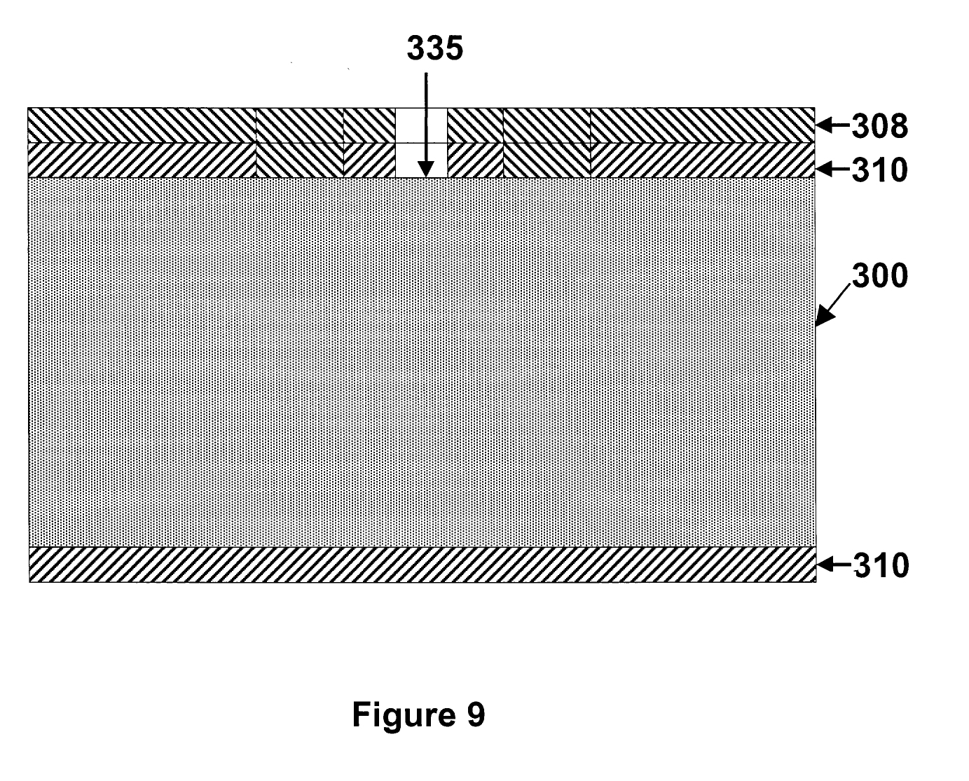

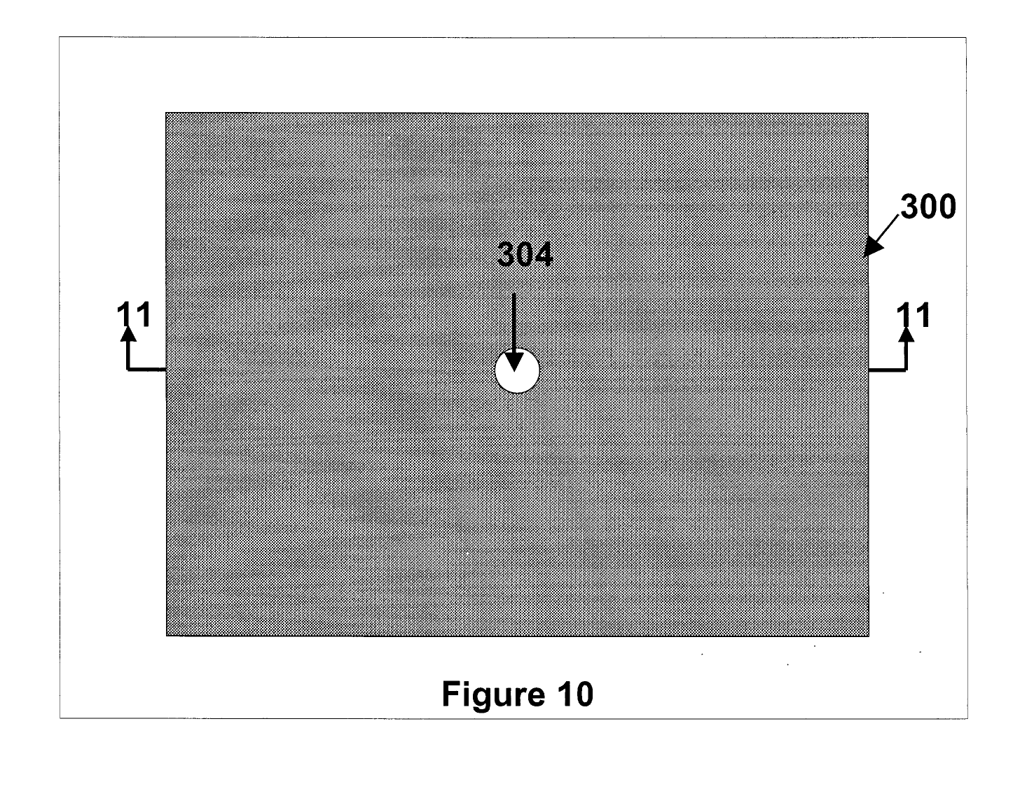

Referring to the cross-sectional view of FIG. 8, a soft mask film of positive-working photoresist 308′ is deposited on the silicon dioxide layer 310 on the nozzle side of the substrate 300. Referring to FIG. 9, an area of the photoresist corresponding to the entrance to through-wafer channels is selectively exposed through a mask (FIG. 10) by an optical lithographic exposure tool passing short-wavelength light, such as blue or near-ultraviolet at wavelengths of 365, 405, or 436 nanometers.

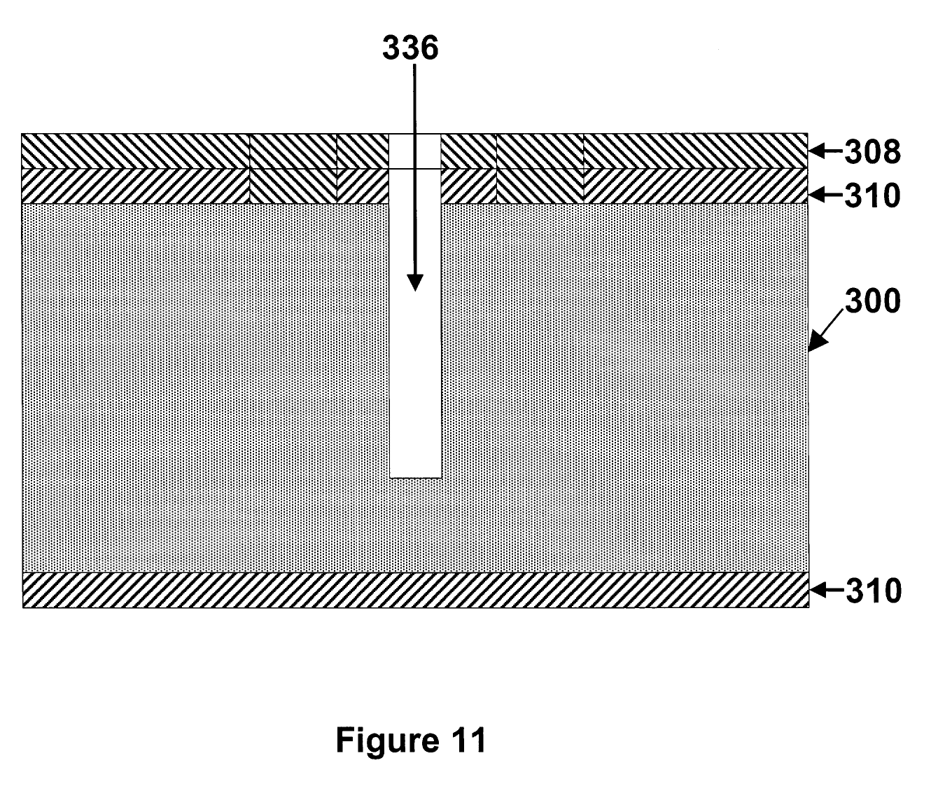

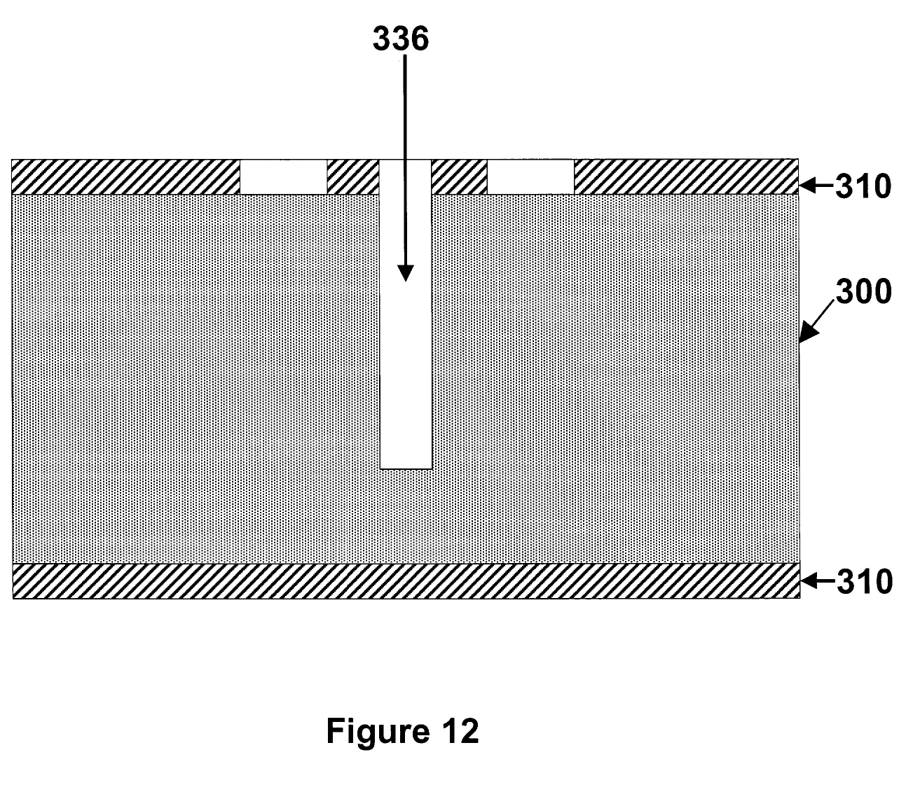

As shown in the cross-sectional view of FIG. 9, after development of the photoresist 308′, the exposed area 304 of the photoresist is removed to the underlying silicon substrate 335. The remaining photoresist 308′ is used as a mask during the subsequent fluorine based DRIE silicon etch to vertically etch the through-wafer channel of the nozzle interior shown in FIG. 11. Preferably, the channel is etched to a depth of from about 20 to about 300 μm. After etching the through-wafer channels 336, the remaining photoresist 308′ is removed from the silicon substrate 300, as shown in FIG. 12.

As shown in the cross-sectional view of FIG. 12, the removal of the photoresist 308′ exposes the mask pattern of FIG. 5 formed in the silicon dioxide 310. An advantage of the fabrication process described herein is that the process simplifies the alignment of the through-wafer channels and the recessed annular region. This allows the fabrication of smaller nozzles with greater ease without any complex alignment of masks. Dimensions of the through channel, such as the aspect ratio (i.e. depth to width), can be reliably and reproducibly limited and controlled.

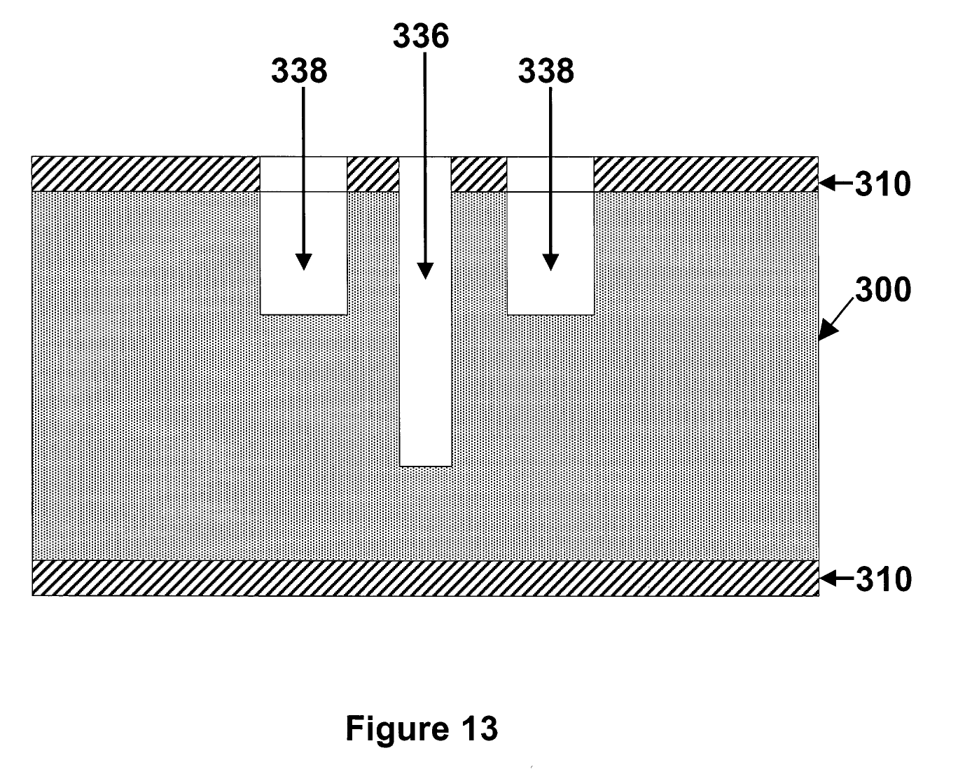

The remaining photoresist 308′ is used as a mask during the subsequent fluorine based DRIE silicon etch to vertically etch the through-wafer channel of the nozzle interior and annulus, as shown in FIG. 13. Preferably, the annulus is etched to a depth of from about 2 to about 200 um.

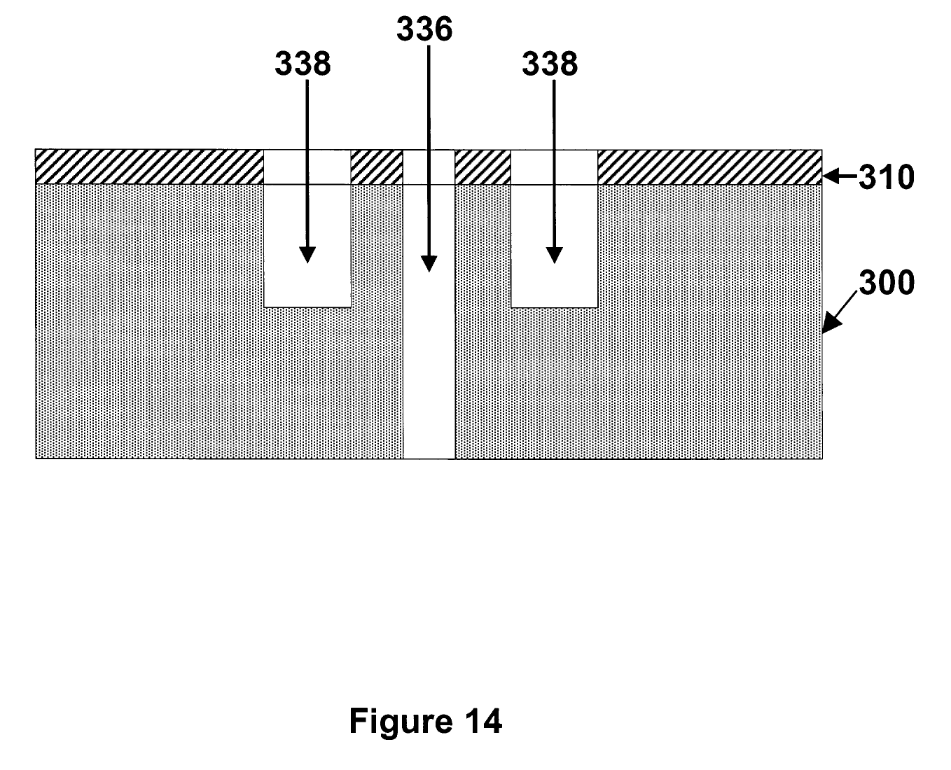

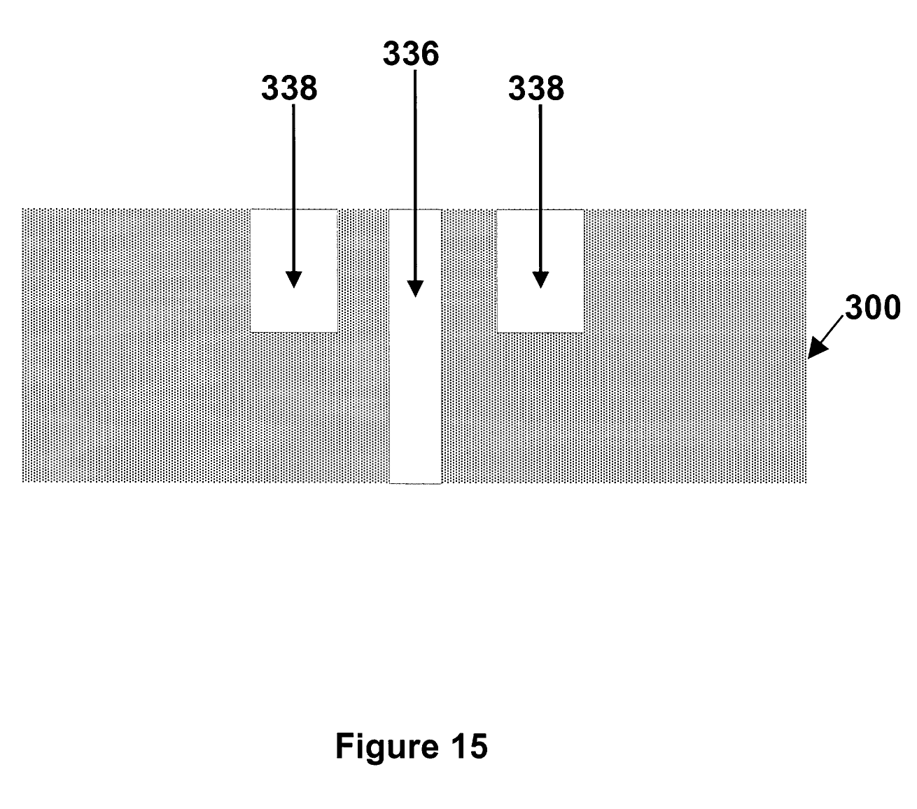

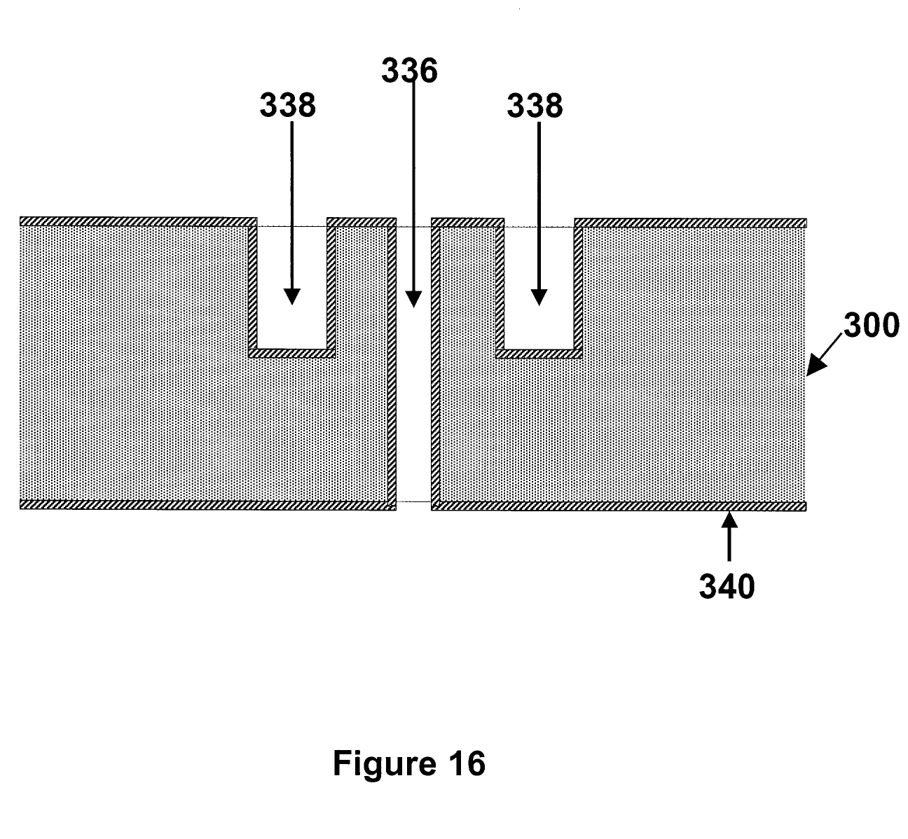

The back side of the wafer is lapped or grinded until the nozzle channel 336 is exposed, as shown in FIG. 14, then the surface is polished. The backgrinding may be performed prior to etching the annulus. In the case of multiple nozzles per wafer, the wafer may be cut into sections, for example with a diamond saw, each section containing desired arrays of multiple nozzles. Preferably, the wafer is cut while still mounted in the lapping fixture. The chips are then cleaned to remove contaminants. The remaining silicon oxide is removed, as shown in FIG. 15. Dielectric layers are grown and deposited on the surface of the chip using standard industry techniques, as shown in FIG. 16.

The dielectric layers provide electrical insulation and a fluid barrier that prevents fluids and ions contained therein that are introduced to the electrospray device from causing an electrical connection between the fluid the silicon substrate 300. This allows for the independent application of a potential voltage to a fluid and the substrate with this electrospray device to generate the high electric field at the nozzle tip required for successful nanoelectrospray of fluids from microchip devices.

Alternately, the wafer can be diced or cut into individual devices after fabrication of multiple electrospray devices on a single silicon wafer. This exposes a portion of the silicon substrate 300 as shown in the cross-sectional view of FIG. 16 on which a layer of conductive metal may be deposited.

The fabrication method confers superior mechanical stability to the fabricated electrospray device by etching the features of the electrospray device from a monocrystalline silicon substrate without any need for assembly. The alignment scheme allows for nozzle walls of less than 2 μm and nozzle outer diameters down to 5 μm to be fabricated reproducibly. Further, the lateral extent and shape of the recessed annular region can be controlled independently of its depth. The depth of the recessed annular region also determines the nozzle height and is determined by the extent of etch on the nozzle side of the substrate.

The above described fabrication sequence for the electrospray device can be easily adapted to and is applicable for the simultaneous fabrication of a single monolithic system including multiple electrospray devices having multiple channels and/or multiple ejection nozzles embodied in a single monolithic substrate. Further, the processing steps may be modified to fabricate similar or different electrospray devices merely by, for example, modifying the layout design and/or by changing the polarity of the photomask and utilizing negative-working photoresist rather than utilizing positive-working photoresist. The following techniques are suitable for use in the present invention: wet etching, dry etching, ablation, embossing and plastic injection molding. Preferred is deep reactive ion etching.

Arrays of electrospray nozzles on a multi-system chip may be interfaced with a sampling orifice of a mass spectrometer by positioning the nozzles near the sampling orifice. The tight configuration of electrospray nozzles allows the positioning thereof in close proximity to the sampling orifice of a mass spectrometer.

A multi-system chip may be manipulated relative to the ion sampling orifice to position one or more of the nozzles for electrospray near the sampling orifice. Appropriate voltage(s) may then be applied to the one or more of the nozzles for electrospray.

The present invention significantly reduces the cost of fabricating electrospray ionization (ESI) devices on chips. This method of fabrication eliminates one photolithography operation, and one deep reactive ion etch operation from prior processes. These two high cost operations are replaced by lower cost mechanical lapping or grinding and polishing operations. In addition this fabrication method eliminates the need for a large inlet feature on the back of the electrospray device which minimizes the volume of the fluid delivery path to the nozzle. The reduced diameter of the nozzle inlet also reduces the diameter of the tips that can be used to supply sample liquid to the chip, and increases the alignment tolerance for tips when aligning to the nozzle inlet. The present method improves coating uniformity and quality when growing and/or depositing coatings on chips rather than on a large wafer. This method of fabrication provides the manufacture of ESI chips at much lower cost while matching or exceeding device quality.

This method applies the nozzle and annulus pattern to the polished side of the wafer, using standard photo resist techniques to pattern and etch the oxide coating. Then using deep reactive ion etching (or alternative etching techniques), the nozzle through channel is etched. The photo resist is then removed. Using the oxide coating as a mask, the wafer is etched to form the annulus and extend the nozzle depth. This is a deep reactive ion etch. Following this etch the wafer may be mounted on appropriate fixtures, as necessary, and the back side of the wafer lapped or ground until the nozzle through channel is exposed. This surface is polished to remove lap or grind damage and smooth the surface. After this polishing, wafers can be cut into individual dies. The exposed nozzle through channels, on the wafer backside, can be used to align the wafer for sawing. After sawing the die may be de-mounted from the fixture and cleaned. Then all oxide is optionally stripped from the die. With the oxide removed, the die is cleaned for application of dielectric layers. Dielectric layers are grown and deposited using standard techniques of the industry. Unwanted dielectric layers on one edge of the die can be removed by chemical etching, grit blasting or mechanical grinding to expose the base silicon. Alternatively, the wafer could be coated with the dielectric films after the backside processing and subsequently diced into individual dies.

Although the invention has been described in detail for the purpose of illustration, it is understood that such detail is solely for that purpose, and variations can be made therein by those skilled in the art without departing from the spirit and scope of the invention which is defined by the following claims.

What is claimed is:

1. A method for fabricating a nozzle on a substrate comprising:
a) providing a substrate;
b) forming at least one channel in the substrate;
c) backgrinding the substrate to create at least one through channel;
d) forming an annulus at the surface of the substrate around the at least one through channel opening to form a nozzle; and
e) cutting the substrate into a plurality of sections, at least one section comprising at least one through channel.

2. The method of claim 1, further comprising polishing the background surface.

3. The method of claim 1, further comprising forming at least one dielectric layer on the surface of the substrate.

4. A method for fabricating a nozzle on a substrate comprising:
a) providing a substrate;
b) forming at least one channel in the substrate;
c) forming an annulus at the surface of the substrate around the at least one channel to form a nozzle;
d) backgrinding the substrate to create at least one through channel; and
e) cutting the substrate into a plurality of sections, at least one section comprising at least one through channel.

5. The method of claim 4, further comprising polishing the background surface.

6. The method of claim 4, further comprising forming at least one dielectric layer on the surface of the substrate.

7. A method for fabricating a nozzle on a substrate comprising:
a) providing a substrate;
b) forming at least one channel in the substrate;
c) backgrinding the substrate to create at least one through channel;
d) forming an annulus at the surface of the substrate around the at least one through channel opening to form a nozzle; and
e) forming a dielectric layer on the surface of the substrate.

8. The method of claim 7, further comprising polishing the background surface.

9. The method of claim 7, further comprising cutting the substrate into a plurality of sections, at least one section comprising at least one through channel.

10. A method for fabricating a nozzle on a substrate comprising:
a) providing a substrate;
b) forming at least one channel in the substrate;
c) forming an annulus at the surface of the substrate around the at least one channel opening to form a nozzle;
d) backgrinding the substrate to create at least one through channel;
c) forming at least one dielectric layer on the surface of the substrate; and
f) cutting the substrate into a plurality of sections, at least one section comprising at least one through channel.

11. The method of claim 10, further comprising polishing the background surface.

12. A method for fabricating a nozzle on a substrate comprising:
a) providing a wafer having at least one side polished;
b) applying a layer of a thermal oxide on the wafer;
c) coating the wafer with photoresist on at least one side;
d) patterning the photoresist to define a nozzle and annulus;
e) etching the pattern in oxide to define the nozzle and annulus;
f) stripping photoresist from the wafer;
g) coating the patterned side of the wafer with photoresist;
h) patterning the photoresist to expose the silicon of the nozzle interior;
i) etching the nozzle interior;
j) stripping photoresist from wafer;
k) etching the annulus;
l) lapping or backgrinding back side of wafer until nozzle channel is exposed, then polishing the surface;
m) cutting wafer into chips;
n) demounting chips from cutting fixture;
o) optionally, stripping all silicon oxide from chips;
p) growing a first dielectric on the chips;
q) depositing a second dielectric over the first dielectric; and
r) removing the dielectric layers from one edge of the chip.

13. A method for fabricating a nozzle on a substrate comprising:
a) providing a wafer having at least one side polished;
b) applying a layer of a thermal oxide on the wafer;
c) coating the wafer with photoresist on one side;
d) patterning the photoresist to define a nozzle and annulus;
e) etching the pattern in oxide to define the nozzle and annulus;
f) stripping photoresist from the wafer;
g) coating the patterned side of the wafer with photoresist;
h) patterning the photoresist to expose silicon of nozzle interior;
i) etching the nozzle interior;
j) stripping photoresist from the wafer;
k) etching the annulus;
l) lapping or backgrinding back side of wafer until a nozzle channel is exposed, then polishing the surface;
m) demounting the wafer from the polishing fixture;
n) optionally, stripping all silicon oxide from chips;
o) growing a first dielectric on the chips;
p) depositing a second dielectric over the first dielectric; and
q) cutting the wafer into chips.

14. A method for fabricating a nozzle on a substrate comprising:
a) providing a wafer having at least one side polished;
b) applying a layer of a thermal oxide on the wafer;
c) coating the wafer with photoresist on one side;
d) patterning the photoresist to define a nozzle and annulus;
e) etching the pattern in oxide to define the nozzle and annulus;
f) stripping photoresist from the wafer;
g) coating the patterned side of the wafer with photoresist;
h) patterning the photoresist to expose silicon of nozzle interior;
i) etching the nozzle interior;
j) stripping photoresist from the wafer;
k) lapping or backgrinding back side of wafer until a nozzle channel is exposed, then polishing the surface;
l) demounting the wafer from the polishing fixture;
m) etching the annulus;
n) optionally, stripping all silicon oxide from chips;
o) growing a first dielectric on the chips;
p) depositing a second dielectric over the first dielectric; and
q) cutting the wafer into chips.

15. A method for fabricating a nozzle on a substrate comprising:
a) providing a wafer having at least one side polished;
b) applying a layer of a thermal oxide on the wafer;
c) coating the wafer with photoresist on one side;
d) patterning the photoresist to define a nozzle and annulus;
e) etching the pattern in oxide to define the nozzle and annulus;
f) stripping photoresist from the wafer;
g) coating the patterned side of the wafer with photoresist;
h) patterning the photoresist to expose silicon of nozzle interior;
i) etching the nozzle interior;
j) stripping photoresist from the wafer;
k) etching the annulus;
l) backgrinding back side of wafer until nozzle channel is exposed;
m) cutting the wafer into chips;
n) demounting the chips from the cutting
fixture;
o) growing a first dielectric on the chips;
p) depositing a second dielectric over the first dielectric; and
n) removing the dielectric layers from one edge of the chip.
